(19) United States
(12) Patent Application Publication
(10) Pub. No.: US 2021/0276131 A1
(43) Pub. Date: Sep. 9, 2021

(54) METHOD FOR MANUFACTURING ELECTRONIC APPARATUS

(71) Applicant: Samsung Display Co., Ltd., Yongin-si (KR)

(72) Inventor: Geunwoo YUG, Seoul (KR)

(21) Appl. No.: 17/119,742

(22) Filed: Dec. 11, 2020

(30) Foreign Application Priority Data
Mar. 4, 2020 (KR) 10-2020-0027113

(51) Int. Cl. B23K 26/364; B23K 26/10; B23K 26/14

(52) U.S. Cl. CPC B23K 26/364; B23K 26/1438; B23K 26/103

(57) ABSTRACT

A method for manufacturing an electronic apparatus, includes: providing a preliminary electronic module including an active area having a hole-forming area, and a peripheral area adjacent to the active area; emitting a laser beam while rotating a laser source along a moving path defined along a boundary between the hole-forming area and the active area, the moving path being divided into a first section and a second section; and removing the hole-forming area from the preliminary electronic module to form an electronic module having a module hole. During a first rotation of the laser source along the moving path, the laser beam is not emitted on the first section, and the laser beam is emitted on the second section.

### CROSS-REFERENCE TO RELATED APPLICATIONS

This application claims priority to and the benefit of Korean Patent Application No. 10-2020-0027113, filed on Mar. 4, 2020, in the Korean Intellectual Property Office, the entire content of which is incorporated by reference herein.

### BACKGROUND

### 1. Field

One or more aspects of example embodiments of the present disclosure relate to a method for manufacturing an electronic apparatus, and more particularly, to an electronic apparatus including electronic components.

### 2. Description of Related Art

Electronic apparatuses are activated in response to electrical signals. The electronic apparatus may include a display unit for displaying an image, and a sensing unit for sensing an external input. In the display unit, an organic light emitting display panel has low power consumption, high luminance, and high reaction speed.

Also, the electronic apparatus may include electronic components for receiving external signals or for providing output signals to the outside. The electronic components are accommodated together with an electronic panel in an outer case or the like to constitute the electronic apparatus.

The above information disclosed in this Background section is for enhancement of understanding of the background of the present disclosure, and therefore, it may contain information that does not constitute prior art.

### SUMMARY

One or more example embodiments of the present disclosure are directed to a method for manufacturing an electronic apparatus in which electronic components having improved durability are provided.

According to one or more example embodiments of the present disclosure, a method for manufacturing an electronic apparatus, includes: providing a preliminary electronic module including an active area having a hole-forming area, and a peripheral area adjacent to the active area; emitting a laser beam while rotating a laser source along a moving path defined along a boundary between the hole-forming area and the active area, the moving path being divided into a first section and a second section; and removing the hole-forming area from the preliminary electronic module to form an electronic module having a module hole. During a first rotation of the laser source along the moving path, the laser beam is not emitted on the first section, and the laser beam is emitted on the second section.

In an example embodiment, after the first rotation, the laser source may emit the laser beam while rotating about one to about 200 times along the moving path.

In an example embodiment, during the first rotation of the laser source, a moving speed of the laser source at the second section may be greater than a moving speed of the laser source at the first section, and after the first rotation, a moving speed of the laser source may be constant.

In an example embodiment, a moving speed of the laser beam may be about 50 mm/s to about 6000 mm/s.

In an example embodiment, a power of the laser beam may be about 0.5 W to about 30 W.

In an example embodiment, a frequency of the laser beam may be about 100 kHz to about 20000 kHz.

In an example embodiment, a start point and an end point of the emitting of the laser beam may be defined on the moving path.

In an example embodiment, the laser beam may be a pulse laser beam.

In an example embodiment, the hole-forming area may have one of a circular, elliptical, or polygonal shape.

In an example embodiment, the hole-forming area may include a plurality of hole-forming areas.

According to one or more example embodiments of the present disclosure, a method for manufacturing an electronic apparatus, includes: providing a preliminary electronic module including an active area having a hole-forming area, and a peripheral area adjacent to the active area; emitting a laser beam while rotating a laser source along a moving path defined along a boundary between the hole-forming area and the active area, the moving path being divided into a first section and a second section; and removing the hole-forming area from the preliminary electronic module to form an electronic module having a module hole. During a first rotation of the laser source along the moving path, the laser source moves at a first speed at the first section, and at a second speed greater than the first speed at the second section.

In an example embodiment, during the first rotation of the laser source along the moving path, the laser beam may not be emitted at the first section, and the laser beam may be emitted at the second section.

In an example embodiment, after the first rotation, the laser source may emit the laser beam while rotating about one to about 200 times along the moving path.

In an example embodiment, after the first rotation, a moving speed of the laser beam may be about 50 mm/s to about 6000 mm/s.

In an example embodiment, a power of the laser beam may be about 0.5 W to about 30 W.

In an example embodiment, a frequency of the laser beam may be about 100 kHz to about 20000 kHz.

In an example embodiment, a start point and an end point of the emitting of the laser beam may be defined on the moving path.

In an example embodiment, the laser beam may be a pulse laser beam.

In an example embodiment, the hole-forming area may have one of a circular, elliptical, or polygonal shape.

According to one or more example embodiments of the present disclosure, a method for manufacturing an electronic apparatus, includes: providing a workpiece substrate including an active area having a hole-forming area and including a plurality of pixels, and a peripheral area adjacent to the active area; emitting a laser beam while rotating a laser source along a moving path defined along a boundary between the hole-forming area and the active area, the moving path being divided into a first section and a second section; and removing the hole-forming area from the workpiece substrate to form a module hole. During a first rotation of the laser source along the moving path, the laser beam is not emitted at the first section, and the laser beam is emitted at the second section.

### BRIEF DESCRIPTION OF THE FIGURES

The above and other aspects and features of the present disclosure will become more apparent to those skilled in the art from the following detailed description of the example embodiments with reference to the accompanying drawings. In the drawings:

FIG. 1 is a perspective view illustrating a coupled state of an electronic apparatus according to an embodiment of the present disclosure;

FIGS. 2A-2B are perspective views of electronic apparatuses according to one or more embodiments of the present disclosure;

FIG. 3A is an exploded perspective view of an electronic apparatus according to an embodiment of the present disclosure;

FIG. 3B is a block diagram of the electronic apparatus illustrated in FIG. 3A;

FIG. 4A is a cross-sectional view illustrating a method for manufacturing an electronic apparatus according to an embodiment of the present disclosure;

FIG. 4B is a plan view illustrating a method for manufacturing an electronic apparatus according to an embodiment of the present disclosure;

FIG. 5A is a cross-sectional view illustrating a method for manufacturing an electronic apparatus according to an embodiment of the present disclosure;

FIG. 5B is a plan view of a preliminary electronic module according to an embodiment of the present disclosure;

FIG. 6A is a perspective view illustrating a method for manufacturing an electronic apparatus according to an embodiment of the present disclosure;

FIG. 6B is a perspective view illustrating a method for manufacturing an electronic apparatus according to an embodiment of the present disclosure;

FIG. 6C is a perspective view illustrating a method for manufacturing an electronic apparatus according to an embodiment of the present disclosure;

FIG. 7 is a cross-sectional view illustrating a method for manufacturing an electronic apparatus according to an embodiment of the present disclosure;

FIG. 8 is a plan view of a preliminary electronic module according to an embodiment of the present disclosure;

FIG. 9 is a plan view of a preliminary electronic module according to an embodiment of the present disclosure; and

FIG. 10 is a plan view of a preliminary electronic module according to an embodiment of the present disclosure.

### DETAILED DESCRIPTION

Hereinafter, example embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, descriptions thereof may not be repeated.

In the drawings, the relative sizes of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” and “including,” “has, ” “have, ” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

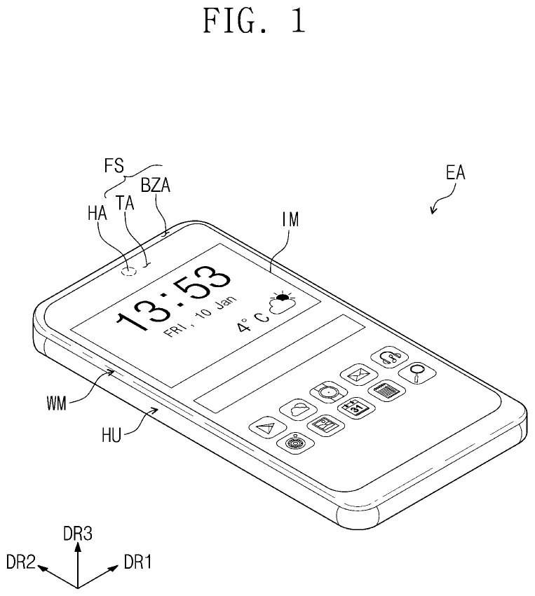

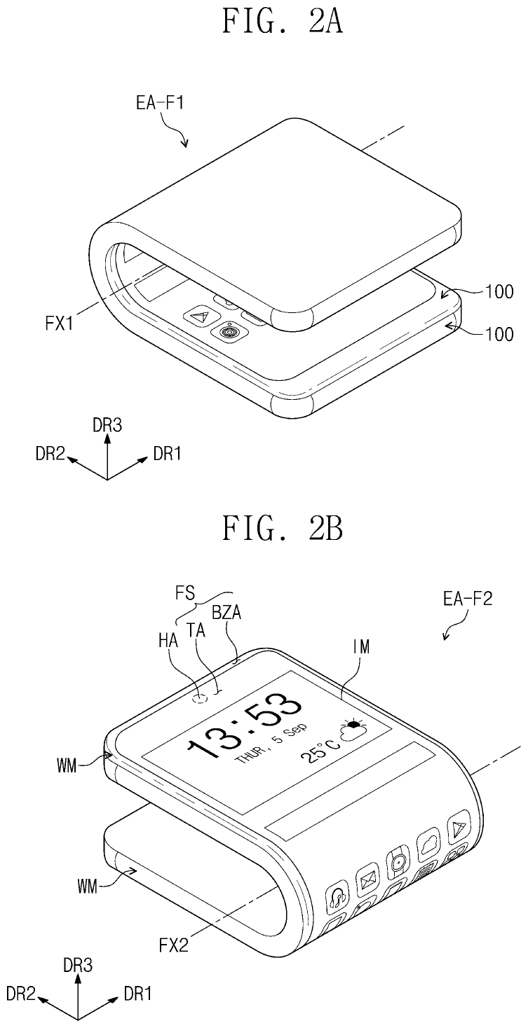

FIG. 1 is a perspective view illustrating a coupled state of an electronic apparatus according to an embodiment of the present disclosure. FIGS. 2A and 2B are perspective views of electronic apparatuses according to one or more embodiments of the present disclosure. FIG. 2A illustrates an electronic apparatus EA of FIG. 1 in a first mode, and FIG. 2B illustrates the electronic apparatus EA of FIG. 1 in a second mode. Hereinafter, an embodiment of the present disclosure will be described with reference to FIGS. 1 to 2B.

The electronic apparatus EA may be an apparatus that may be activated in response to an electrical signal. The electronic apparatus EA may include various suitable embodiments. For example, the electronic apparatus EA may include a tablet, a laptop, a computer, a smart television, and/or the like. In the embodiment shown in FIG. 1, the electronic apparatus EA is illustratively shown as a smart phone.

The electronic apparatus EA displays an image IM at (e.g., in or on) a transmission area TA. The image IM may include at least one of a static image or a dynamic image. In FIG. 1, a clock and a plurality of icons are illustrated as an example of the image IM.

The transmission area TA may have a quadrangular shape having sides that are each parallel to or substantially parallel to a first direction DR1 or a second direction DR2. However, the present disclosure is not limited thereto, and this is merely illustrated as an example. The transmission area TA may have various suitable shapes, but is not limited to any particular example.

A bezel area BZA is adjacent to the transmission area TA. For example, the bezel area BZA may surround (e.g., around a periphery of) the transmission area TA. However, the present disclosure is not limited thereto as this is merely illustrated as an example, and in other embodiments, for example, the bezel area BZA may be disposed adjacent to only one side of the transmission area TA or may be omitted. The electronic apparatus according to one or more example embodiments of the present disclosure may include various suitable embodiments and is not limited to any particular example.

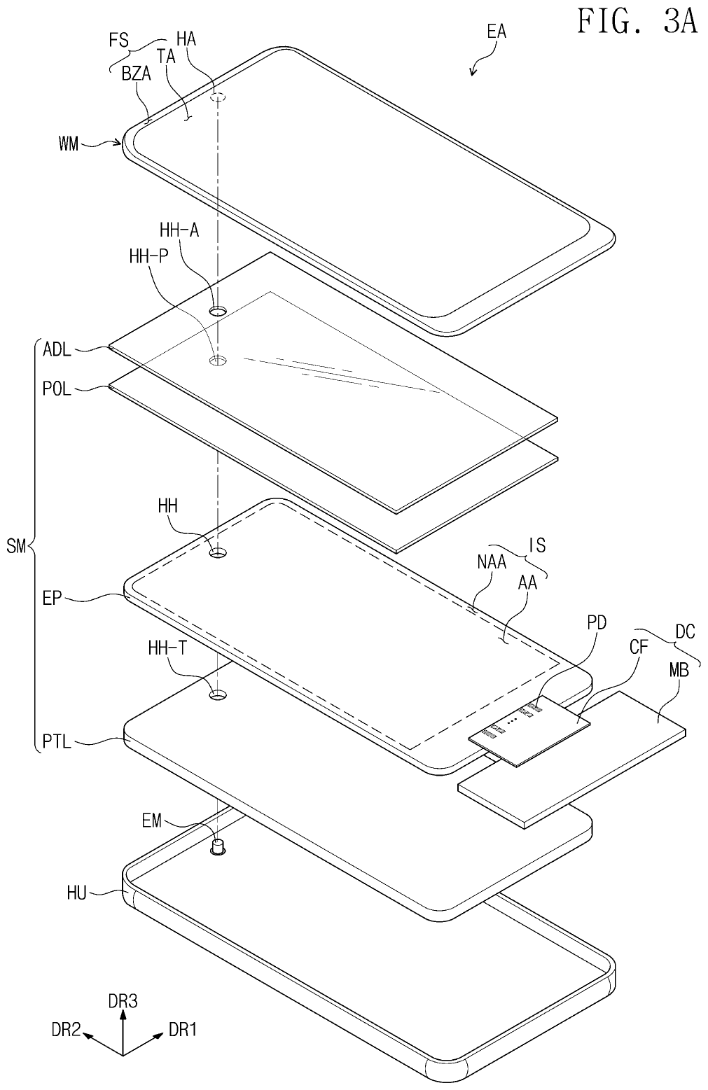

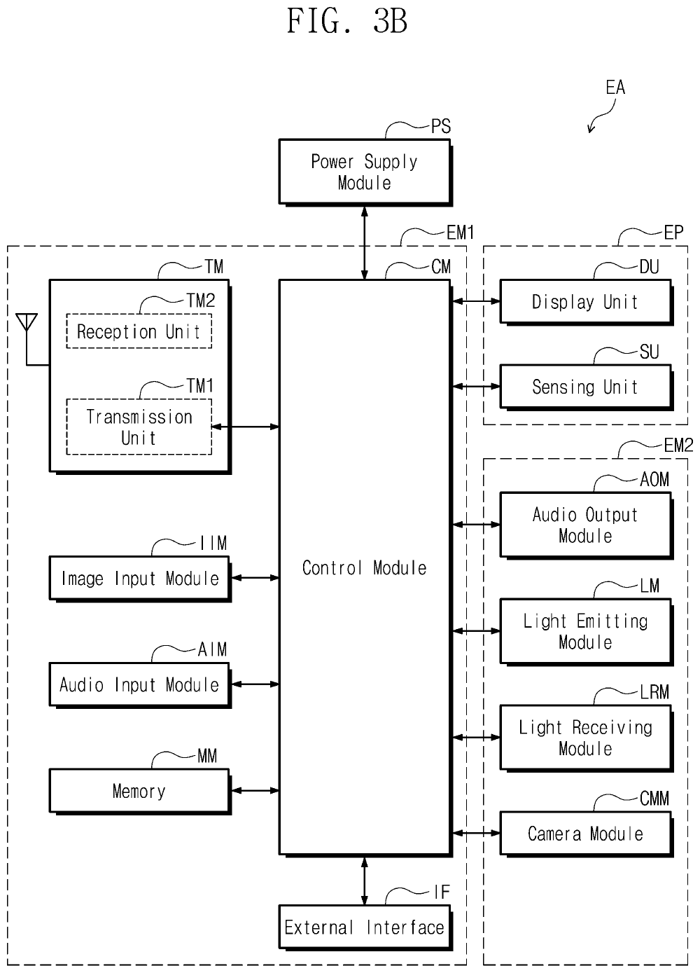

In the electronic apparatus EA according to the present embodiment, a hole area HA may be defined. The hole area HA may be an area overlapping with an electronic component EA (e.g., see FIG. 3A), which will be described in more detail below. In other words, the hole area HA may be an area in which a camera and/or the like for capturing an image of an external object is disposed, or an area in which a photo sensor for sensing light is disposed. The image IM may be displayed, such that the image IM may surround at least a portion of an edge of the hole area HA. In the present embodiment, the image IM is displayed while surrounding (e.g., around a periphery of) the hole area HA. This will be described in more detail below.

A normal direction of a front surface FS may correspond to a thickness direction DR3 (hereinafter, referred to as a third direction) of the electronic apparatus EA. In the present embodiment, a front surface (or a top surface) and a rear surface (or a bottom surface) for each member are defined with respect to the direction in which the image IM is displayed. The front surface and the rear surface are opposite to each other in the third direction DR3.

In the present specification, directions indicated as the first to third directions DR1, DR2, and DR3 may have a relative concept, and thus, may be changed to other suitable directions. Hereinafter, the first to third directions DR1, DR2, and DR3 refer to the same reference symbols shown in the figures and indicated by the first to third directions DR1, DR2, and DR3, respectively.

An exterior of the electronic apparatus EA may have an appearance which may be defined by a window WM and an outer case HU. The front surface FS of the electronic apparatus EA may be defined or substantially defined by the window WM.

As illustrated in FIGS. 2A and 2B, the electronic apparatus EA may be folded around (e.g., folded along) folding axes (e.g., predetermined folding axes) FX1 and FX2. For example, as illustrated in FIG. 2A, an electronic apparatus EA-F1 may be folded around (e.g., may be folded along) a first folding axis FX1. The first folding axis FX1 may be defined on the window WM. Accordingly, the electronic apparatus EA-F1 in a first mode is folded into a state in which different portions of the window WM face each other, and the outer case HU is exposed to the outside.

In another example, as illustrated in FIG. 2B, an electronic apparatus EA-F2 may be folded around (e.g., folded along) a second folding axis FX2. The second folding axis FX2 may be defined on the outer case HU. Accordingly, the electronic apparatus EA-F2 in a second mode is folded into a state in which different portions of the outer case HU face each other, and the window WM is exposed to the outside. An image displayed by the electronic apparatus EA-F2 may be viewed (e.g., may be easily viewed) by a user even in a state in which the electronic apparatus EA-F2 is folded.

In some embodiments, the electronic apparatus EA of FIG. 1 may be folded along both the first folding axis FX1 in the first mode, and the second folding axis FX2 in the second mode, or may be folded along only one from among the first folding axis FX1 and the second folding axis FX2, such that the electronic apparatus EA may be folded in only one of the first mode or the second mode.

For example, in an embodiment, both the first folding axis FX1 and the second folding axis FX2 may be provided in the electronic apparatus EA. In this example, the electronic apparatus EA may be transformed into the electronic apparatus EA-F1 in the first mode, and/or may be transformed into the electronic apparatus EA-F2 in the second mode, depending on a direction of an external force. In another embodiment, either the first folding axis FX1 or the second folding axis FX2 may be selectively provided in the electronic apparatus EA. Further, extension directions of the first folding axis FX1 and the second folding axis FX2 are not limited to those illustrated in FIGS. 2A and 2B, and may be defined as various suitable directions. The extension directions thereof are not limited to any particular example.

The electronic apparatus EA according to an embodiment of the present disclosure may be folded around (e.g., folded along) preset or predetermined folding axes FX1 and FX2. However, the present disclosure is not limited thereto, and this is merely described as an example. The electronic apparatus EA may have rigid characteristics, but is not limited to any particular example.

FIG. 3A is an exploded perspective view of an electronic apparatus according to an embodiment of the present disclosure. FIG. 3B is a block diagram of the electronic apparatus illustrated in FIG. 3A.

As illustrated in FIG. 3A, an electronic apparatus EA may include a window WM, an electronic module SM, an electronic component EM, and an outer case HU.

In the present embodiment, the electronic module SM may include an electronic panel EP, an optical film POL, an adhesive layer ADL, a circuit board DC, and a protective layer PTL. As described above, the window WM and the outer case HU are connected to each other to define the exterior of the electronic apparatus EA.

The window WM is disposed on the electronic panel EP to cover a front surface IS of the electronic panel EP. The window WM may include an optically transparent insulating material. Also, the window WM may be flexible. For example, the window WM may include a resin film or a resin substrate having polyimide and/or the like, or a glass substrate having a thin film.

The window WM may have a multi-layered structure or a single-layer structure. For example, the window WM may have a structure in which a plurality of plastic films are stacked on and connected to each other through adhesives, or a structure in which the glass substrate is stacked on and connected to a plastic film through an adhesive.

The window WM may include a front surface FS exposed to the outside. The front surface FS of the electronic apparatus EA may be defined or substantially defined by the front surface FS of the window WM. For example, a transmission area TA of the front surface FS of the window WM may be an optically transparent area. The transmission area TA may have a shape corresponding to an active area AA. For example, the transmission area TA overlaps with the entire surface of the active area AA, or at least a portion of the active area AA. An image IM displayed on the active area AA of the electronic panel EP may be viewed from the outside through the transmission area TA.

A bezel area BZA may be an area having a relatively lower light transmittance than that of the transmission area TA. The bezel area BZA defines a shape of the transmission area TA. The bezel area BZA is adjacent to the transmission area TA, and may surround (e.g., around a periphery of) the transmission area TA.

The bezel area BZA may have a suitable color (e.g., a predetermined color). For example, when the window WM is provided as a glass or a plastic substrate, the bezel area BZA may be a color layer which is printed or deposited on one surface of the glass or the plastic substrate. In another example, the bezel area BZA may be formed by coloring a relevant area of the glass or the plastic substrate.

The bezel area BZA may cover a peripheral area NAA of the electronic panel EP to prevent or substantially prevent the peripheral area NAA from being viewed from the outside. However, the present disclosure is not limited thereto, and this is merely illustrated as an example. For example, the bezel area BZA may be omitted in the window WM according to an embodiment of the present disclosure.

The electronic panel EP displays an image IM. The electronic panel EP includes the front surface IS having the active area AA and the peripheral area NAA. The active area AA may be an area which is activated in response to an electrical signal.

In the present embodiment, the active area AA may be an area on which the image IM is displayed. The transmission area TA overlaps with at least the active area AA. For example, the transmission area TA overlaps with the entire surface of the active area AA, or at least a portion of the active area AA. Accordingly, the image IM may be viewed by a user through the transmission area TA.

The peripheral area NAA may be an area covered by the bezel area BZA. The peripheral area NAA is adjacent to the active area AA. The peripheral area NAA may cover an edge of the active area AA. A driving circuit, a driving line, and/or the like for driving the active area AA may be disposed at (e.g., in or on) the peripheral area NAA.

For example, various signal lines and pads PD for providing electrical signals to the active area AA, electronic elements, and/or the like may be disposed at (e.g., in or on) the peripheral area NAA. The peripheral area NAA is covered by the bezel area BZA, and thus, may not be viewed (or may not be easily viewed) from the outside.

In the present embodiment, the electronic panel EP is assembled while the active area AA and the peripheral area NAA are in a flat state facing the window WM. However, the present disclosure is not limited thereto, and this is merely illustrated as an example. For example, a portion of the peripheral area NAA in the electronic panel EP may be bent. In this example, the portion of the peripheral area NAA faces a rear surface of the electronic apparatus EA, and thus, the bezel area BZA of the front surface FS may be reduced. In another example, the electronic panel EP may be assembled while a portion of the active area AA is also bent. In another example, in the electronic panel EP according to an embodiment of the present disclosure, the peripheral area NAA may be omitted.

A panel hole HH may be defined in the electronic panel EP. At least a portion of the panel hole HH may be surrounded (e.g., around a periphery thereof) by the active area AA. In the present embodiment, the panel hole HH may be spaced apart from the peripheral area NAA. The panel hole HH may be defined within the active area AA, such that an entire edge of the panel hole HH is surrounded by the active area AA. In a coupled state of the electronic apparatus EA according to the present embodiment, the panel hole HH may overlap with the transmission area TA, and may be provided at a position spaced apart from the bezel area BZA.

The circuit board DC may be connected to the electronic panel EP. The circuit board DC may include a flexible board CF and a main board MB. The flexible board CF may include an insulating film, and conductive lines on (e.g., mounted on) the insulating film. The conductive lines are connected to the pads PD, and thus, the circuit board DC and the electronic panel EP are electrically connected to each other.

In the present embodiment, the flexible board CF may be assembled in a curved state. In this example, the main board MB is disposed on the rear surface of the electronic panel EP, and thus, may be stably accommodated within a space provided by the outer case HU. However, the present disclosure is not limited thereto, and in another embodiment, the flexible board CF may be omitted, and the main board MB may be directly connected to the electronic panel EP.

The main board MB may include signal lines and electronic elements. The electronic elements are connected to the signal lines, and thus, may be electrically connected to the electronic panel EP. The electronic elements generate various suitable electrical signals, for example, such as a signal for producing the image IM and/or a signal for sensing an external input, or may perform processing on the sensed signals. In an example, the main board MB may be provided in a plurality to correspond to the electrical signals for the generation and processing, respectively, but the present disclosure is not limited to any particular example.

In the electronic apparatus EA according to an embodiment of the present disclosure, the driving circuit for providing the electrical signal to the active area AA may be directly on (e.g., directly mounted on) the electronic panel EP. In this example, the driving circuit may be mounted as a chip or may be formed together with pixels PX. Thus, the circuit board DC may have a reduced surface area or may be omitted. The electronic apparatus EA according to an embodiment of the present disclosure may have various suitable embodiments, and is not limited to any particular example.

The optical film POL may be disposed between the window WM and the electronic panel EP. The optical film POL may decrease reflectivity of external light, which may be incident from the outside of the window WM, with respect to the electronic panel EP. In the present embodiment, the optical film POL may include a polarization film or a color filter.

In the optical film POL, a hole (e.g., a predetermined hole) HH-P (hereinafter, referred to as an optical film hole) passing through the optical film POL may be defined. The optical film hole HH-P may be defined in an area corresponding to the panel hole HH of the electronic panel EP. In the present embodiment, the optical film hole HH-P is illustrated as being located at a position that overlaps with the panel hole HH of the electronic panel EP, and having the same or substantially the same shape as that of the panel hole HH. However, the present disclosure is not limited thereto, and this is merely illustrated as an example. For example, in other embodiments, the position and/or size of the optical film hole HH-P may be different from the position and/or size of the panel hole HH of the electronic panel EP due to a difference in a process and/or the like.

The adhesive layer ADL is disposed between the optical film POL and the window WM. The optical film POL and the window WM are connected to each other through the adhesive layer ADL. However, the present disclosure is not limited thereto, and when the optical film POL according to an embodiment of the present disclosure is a color filter provided in the electronic panel EP, the electronic panel EP and the window WM may be connected to or substantially connected to each other through the adhesive layer ADL. The adhesive layer ADL may include an optical clear adhesive, an optical clear resin, or a pressure sensitive adhesive. However, the present disclosure is not limited to any particular example of the adhesive layer ADL, as long as the adhesive layer ADL is optically transparent. In some embodiments, a plurality of adhesive layers may be provided, which are disposed between various components of the electronic module SM to connect the components to one another.

In the adhesive layer ADL, a hole (e.g., a predetermined hole) HH-A (hereinafter, referred to as an adhesive layer hole) passing through the adhesive layer ADL may be defined. The adhesive layer hole HH-A may be provided along the panel hole HH of the electronic panel EP. In the present embodiment, the adhesive layer hole HH-A and the optical film hole HH-P are illustrated as being aligned with the panel hole HH of the electronic panel. However, the present disclosure is not limited thereto, and this is merely illustrated as an example. For example, each of the adhesive layer hole HH-A and the optical film hole HH-P may have a step portion (e.g., a predetermined step portion) with respect to the panel hole HH of the electronic panel due to a difference in a process and/or the like.

The protective layer PTL is disposed below the electronic panel EP. The protective layer PTL may include (e.g., may be made of) a plurality of layers. The protective layer PTL may include various suitable layers for reducing stress applied to the electronic panel EP when folded, and for protecting the electronic panel EP from an external impact. For example, the protective layer PTL may include a cushion layer having a foam shape for absorbing an impact to the electronic panel EP, a light blocking layer for blocking light from the electronic panel EP, and a heat dissipation layer for discharging heat, for example, generated from the electronic panel EP, to the outside.

In the protective layer PTL, a hole (e.g., a predetermined hole) HH-T (hereinafter, referred to as a protective layer hole) passing through the protective layer PTL may be defined. The protective layer hole HH-T may be provided along the panel hole HH of the electronic panel EP. In the present embodiment, the protective layer hole HH-T, the adhesive layer hole HH-A, and the optical film hole HH-P are illustrated as being aligned with the panel hole HH of the electronic panel. However, the present disclosure is not limited thereto, and this is merely illustrated as an example. For example, each of the protective layer hole HH-T, the adhesive layer hole HH-A, and the optical film hole HH-P may have a step portion (e.g., a predetermined step portion) with respect to the panel hole HH of the electronic panel due to a difference in a process and/or the like.

The electronic component EM is disposed below the window WM. In a plan view, the electronic component EM may overlap with the panel hole HH. The electronic component EM may receive an external input transmitted through the panel hole HH, or may provide an output through the panel hole HH.

In the electronic component EM, a reception part for receiving the external input and/or an output part for providing the output may overlap with the panel hole HH in a plan view. According to an embodiment of the present disclosure, the electronic component EM is disposed overlapping with the active area AA, and thus, an increase in the bezel area BZA may be prevented or reduced.

Referring to FIG. 3B, an electronic apparatus EA may include an electronic panel EP, a power supply module (e.g., a power supply) PS, a first electronic component EM1, and a second electronic component EM2. The electronic panel EP, the power supply module PS, the first electronic component EM1, and the second electronic component EM2 may be electrically connected to each other.

In FIG. 3B, the electronic panel EP may include a display unit (e.g., a display layer) DU and a sensing unit (e.g., a sensing layer) SU. The display unit DU may include pixels which are driven by at least one or more transistors. The sensing unit SU may sense an external input applied to the window WM. The external input may include various suitable kinds of inputs, for example, such as a portion of the body of a user (e.g., a finger) utilizing the electronic apparatus EA, light, heat, and/or pressure provided from the outside. The electronic apparatus EA may sense an input contacting the electronic apparatus EA, and/or may sense an input that is approaching (e.g., that is proximal to) or adjacent to the electronic apparatus EA. The sensing unit SU may be stacked on the display unit DU, or may be inserted into and integrated with the display unit DU.

Each of the first electronic component EM1 and the second electronic component EM2 includes various functional modules (e.g., functional devices, circuits, and/or the like) for operating the electronic apparatus EA. The first electronic component EM1 may be directly connected to (e.g., directly mounted on) a mother board electrically connected to the electronic panel EP, or may be connected to (e.g., mounted on) a separate substrate and electrically connected to a mother board through a connector and/or the like.

The first electronic component EM1 may include a control module (e.g., a controller) CM, a wireless communication module (e.g., a wireless communication device or circuit) TM, an image input module (e.g., an image input device or circuit) IIM, an audio input module (e.g., an audio input device or circuit) AIM, a memory MM, and an external interface IF. Some of the modules may not be mounted on the mother board, but may be electrically connected to the mother board through a flexible circuit board.

The control module CM controls operations (e.g., overall operations) of the electronic apparatus EA. In some embodiments, the control module CM may be a microprocessor. For example, the control module CM activates and/or deactivates the electronic panel EP. The control module CM may control other modules, for example, such as the image input module IIM and/or the audio input module AIM on the basis of a touch signal received from the electronic panel EP.

The wireless communication module TM may receive and transmit a wireless signal from and to another terminal by using, for example, a Bluetooth line, a Wi-Fi line, and/or the like. The wireless communication module TM may receive and transmit an audio signal by using, for example, a general communication line. The wireless communication module TM includes a transmission unit (e.g., a transmitter) TM1 for modulating and transmitting a signal, and a reception unit (e.g., a receiver) TM2 for demodulating a received signal.

The external interface IF serves as an interface connected to an external charger, wired/wireless data ports, a card socket (e.g., to receive a memory card, a SIM/UIM card, and/or the like), and/or the like.

The second electronic component EM2 may include an audio output module (e.g., an audio output device or circuit) AOM, a light emitting module (e.g., a light emitting device or circuit) LM, a light receiving module (e.g., a light receiving device or circuit) LRM, and a camera module (e.g., a camera device or circuit) CMM. These components may be directly mounted on a mother board, may be mounted on a separate substrate and electrically connected to the electronic panel EP through a connector and/or the like, or may be electrically connected to the first electronic component EM1.

The audio output module AOM converts audio data received from the wireless communication module TM and/or audio data stored in the memory MM, and then outputs the converted audio data to the outside.

The light emitting module LM generates and outputs light. The light emitting module LM may output infrared light. For example, the light emitting module LM may include an LED element. For example, the light receiving module LRM may sense infrared light. The light receiving module LRM may be activated when the infrared light having a suitable level (e.g., a predetermined level or higher) is sensed. The light receiving module LRM may include a CMOS sensor. The infrared light generated by the light emitting module LM is output and then reflected from an external object (e.g., the finger or face of a user). The reflected infrared light may be incident onto the light receiving module LRM. The camera module CMM captures an external image.

The electronic component EM according to an embodiment of the present disclosure may include at least one of the elements of the first electronic component EM1 or the second electronic component EM2. For example, the electronic component EM may include at least one of a camera, a speaker, a light detection sensor, or a heat detection sensor. The electronic component EM may sense an external object through the panel hole HH, and may provide a sound signal such as voice to the outside through the panel hole HH. However, the present disclosure is not limited thereto, and the electronic component EM may include a plurality of elements and is not limited to any particular example.

According to an embodiment of the present disclosure, the electronic component EM may be assembled to overlap with the transmission area TA in a plan view. Accordingly, an increase in the bezel area BZA due to accommodation of the electronic component EM may be prevented or reduced, and thus, the appearance of the electronic apparatus EA may be improved.

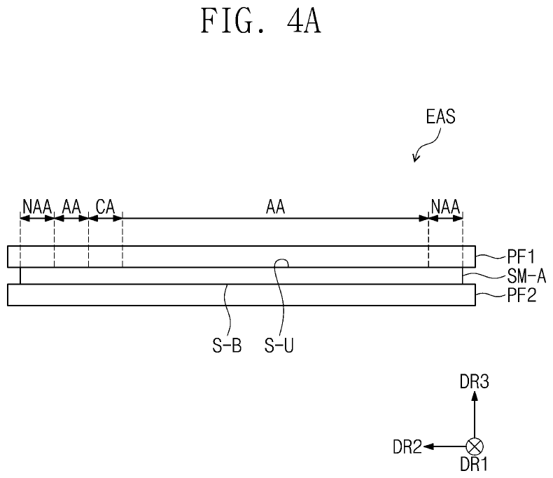

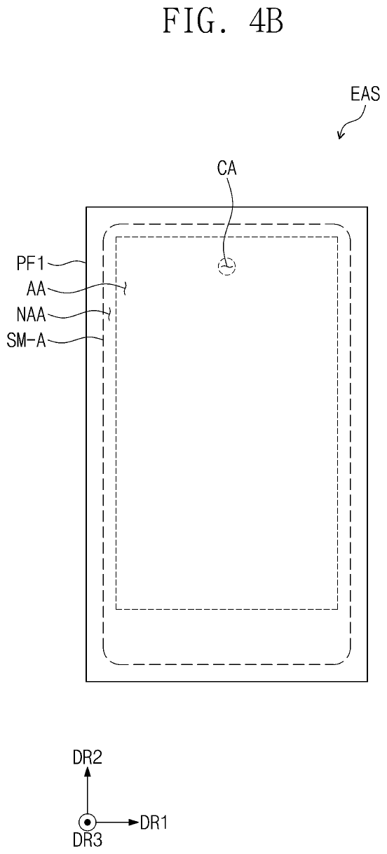

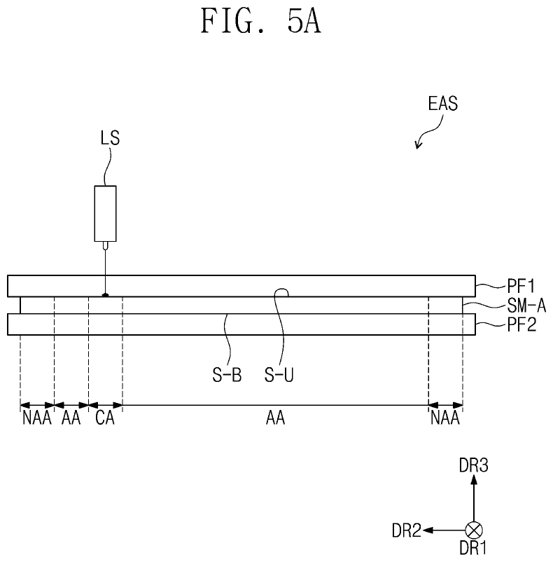

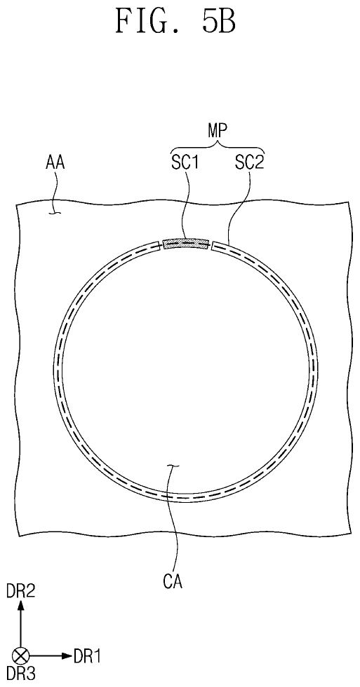

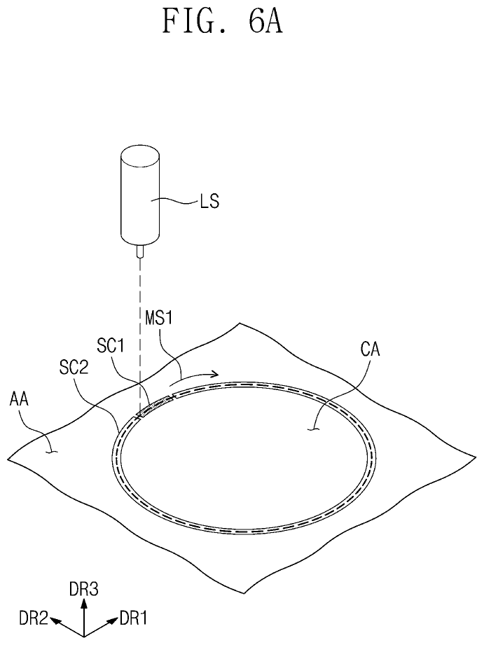

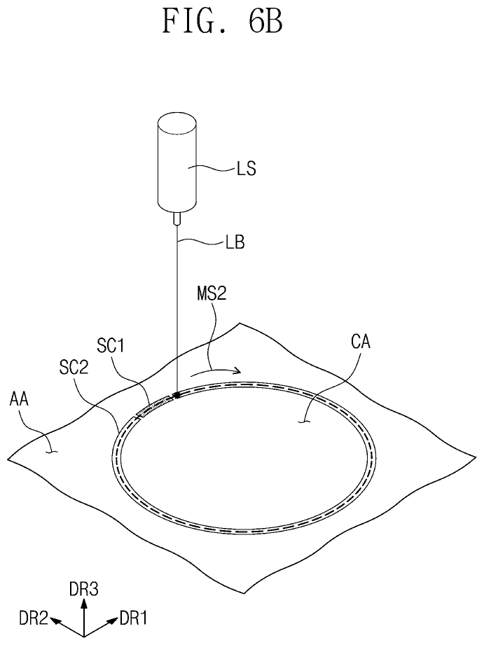

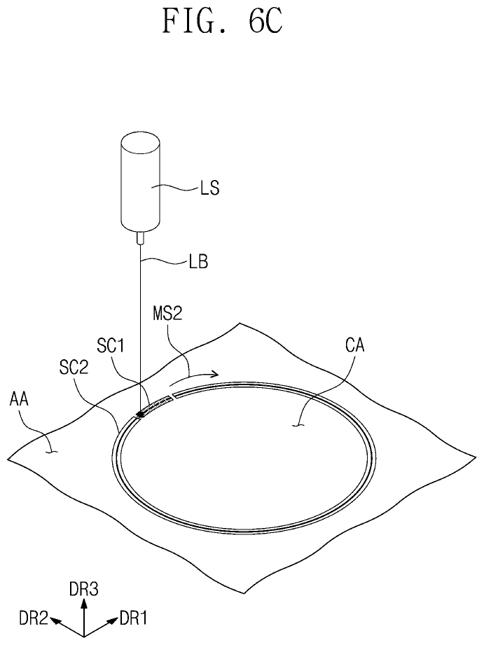

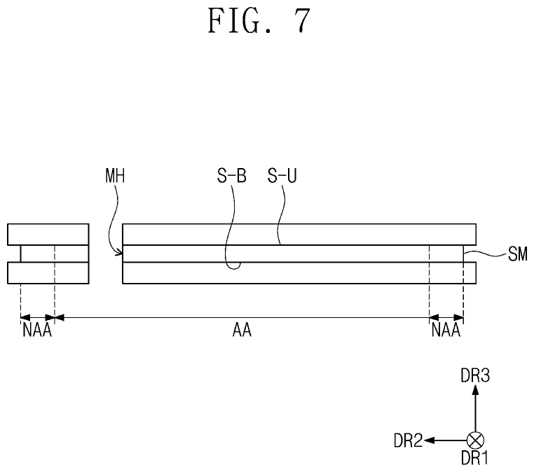

FIG. 4A is a cross-sectional view illustrating a method for manufacturing an electronic apparatus according to an embodiment of the present disclosure. FIG. 4B is a plan view illustrating a method for manufacturing an electronic apparatus according to an embodiment of the present disclosure. FIG. 5A is a cross-sectional view illustrating a method for manufacturing an electronic apparatus according to an embodiment of the present disclosure. FIG. 5B is a plan view of a preliminary electronic module according to an embodiment of the present disclosure. FIG. 6A is a perspective view illustrating a method for manufacturing an electronic apparatus according to an embodiment of the present disclosure. FIG. 6B is a perspective view illustrating a method for manufacturing an electronic apparatus according to an embodiment of the present disclosure. FIG. 6C is a perspective view illustrating a method for manufacturing an electronic apparatus according to an embodiment of the present disclosure. FIG. 7 is a cross-sectional view illustrating a method for manufacturing an electronic apparatus according to an embodiment of the present disclosure.

Hereinafter, a method for manufacturing an electronic apparatus according to an embodiment of the present disclosure will be described with reference to FIGS. 4A to 7. More particularly, a method for manufacturing an electronic apparatus, in which the holes HH-A, HH-P, HH, and HH-T overlapping with the electronic component EM are formed in the electronic module SM (e.g., see FIG. 3A), will be described in more detail.

In FIGS. 4A to 7, the same or substantially the same (or similar) reference symbols are used to refer to the same or substantially the same (or similar) elements of those of FIGS. 1 to 3B, and thus, redundant descriptions thereof may not be repeated.

The method for manufacturing an electronic apparatus according to the present embodiment includes providing a workpiece substrate EAS. The workpiece substrate EAS may include a preliminary electronic module SM-A and protective films PF1 and PF2.

In the present embodiment, the preliminary electronic module SM-A may be defined as one or more elements before the holes HH-A, HH-P, HH, and HH-T are formed in the one or more elements of the electronic module SM illustrated in FIG. 3A. Thus, the preliminary electronic module SM-A may include an electronic panel EP, an optical film POL, an adhesive layer ADL, and a protective layer PTL, without the holes HH-A, HH-P, HH, and HH-T being formed therein. Hereinafter, for convenience of illustration, a circuit board DC is omitted from FIGS. 4A to 7.

Referring to FIGS. 4A and 4B, the preliminary electronic module SM-A includes an active area AA having a hole-forming area CA, and a peripheral area NAA adjacent to the active area AA. The preliminary electronic module SM-A includes a top surface S-U and a bottom surface S-B opposite to the top surface S-U.

The hole-forming area CA may be defined as an area overlapping with the electronic component EM illustrated in FIG. 3A. In the present embodiment, the hole-forming area CA is defined as being disposed at (e.g., in or on) a top portion (e.g., a top left portion) of the active area AA, but the present disclosure is not limited thereto. For example, as long as the hole-forming area CA is defined within the active area AA, the shape and/or the number of the hole-forming area CA is not limited to any particular example.

Each of the protective films PF1 and PF2 may be disposed on at least one of the top surface S-U or the bottom surface S-B of the preliminary electronic module SM-A. In some embodiments, the protective films PF1 and PF2 may be attached to the preliminary electronic module SM-A through an adhesive layer.

The protective films PF1 and PF2 may function to protect the preliminary electronic module SM-A from an impact occurring during transporting, conveying, assembling, and/or the like of the preliminary electronic module SM-A. The protective films PF1 and PF2 may prevent or substantially prevent external moisture from permeating into the preliminary electronic module SM-A, and may absorb an external impact. The protective films PF1 and PF2 may prevent or substantially prevent residues, which may be produced while a hole is being formed in the preliminary electronic module SM-A, from flowing into the preliminary electronic module SM-A.

Each of the protective films PF1 and PF2 may include a plastic film as a base layer. In this example, the protective films PF1 and PF2 may include one selected from the group consisting of polyethersulphone (PES), polyacrylate (PAR), polyetherimide (PEI), polyethyelenen napthalate (PEN), polyethyeleneterepthalate (PET), polyphenylene sulfide (PPS), polyallylate, polyimide (PI), polycarbonate (PC), poly(aryleneether sulfone), and a combination thereof.

However, the present disclosure is not limited thereto, and a material constituting the protective films PF1 and PF2 is not limited to plastic resin. For example, the protective films PF1 and PF2 may include an organic/inorganic composite material. The protective films PF1 and PF2 may include a porous organic layer, and inorganic substances filled into the pores of the porous organic layer. The protective films PF1 and PF2 may further include a functional layer disposed on a plastic film. The functional layer may include a resin layer. The functional layer may be formed through a coating method. However, the present disclosure is not limited thereto, and in an embodiment of the present disclosure, the protective films PF1 and PF2 may be omitted.

Referring to FIGS. 5A and 5B, a laser unit (e.g., a laser source) LS emits a laser beam onto the top surface S-U of the preliminary electronic module SM-A. A method for manufacturing an electronic apparatus according to an embodiment of the present disclosure includes emitting a laser beam while rotating the laser unit LS along a moving path MP, which is defined along a boundary between the active area AA and the hole-forming area CA and includes (e.g., is divided into) a first section SC1 and a second section SC2.

Hereinafter, for convenience of illustration, each of the first section SC1 and the second section SC2 is shown as having a band shape that surrounds the moving path MP indicated as a dotted line, and the first section SC1 is shown as hatch areas.

According to an embodiment of the present disclosure, the laser unit LS may move (e.g., may slowly move) in a preset or predetermined section until the laser unit LS reaches a desired moving speed. Here, in the section irradiated with the laser beam at a low speed, laser beams may excessively overlap with each other, and may damage one or more elements disposed within the preliminary electronic module SM-A. Accordingly, a crack may occur in a module hole MH, and a peeling phenomenon may occur and/or particles may be generated at (e.g., in or on) a cracked portion. Also, moisture, oxygen, foreign substances, and/or the like may flow into the module hole MH from the outside through the cracked portion.

An embodiment of the present disclosure includes a section which is not irradiated with the laser beam until the laser unit LS reaches the desired moving speed during a first rotation along the moving path MP, and thus, a method for manufacturing an electronic apparatus in which the cracks discussed above are prevented or reduced may be provided.

For example, referring to FIGS. 6A and 6B, during a first rotation of the laser unit LS along the moving path MP, the first section SC1 may be defined as a section that is not irradiated with a laser beam. The second section SC2 may be defined as a section that begins to be irradiated with a laser beam LB after the laser unit LS reaches a desired moving speed. The second section SC2 may be connected to both ends of the first section SC1.

During the first rotation of the laser unit LS along the moving path MP, a moving speed of the laser unit LS at (e.g., in or on) the first section SC1 may be different from a moving speed of the laser unit LS at (e.g., in or on) the second section SC2. For example, during the first rotation along the moving path MP, the laser unit LS may have a first moving speed MS1 at (e.g., in or on) the first section SC1, and may have a second moving speed MS2 greater than the first moving speed MS1 at (e.g., in or on) the second section SC2. Thus, during the first rotation of the laser unit LS along the moving path MP, the moving speed at (e.g., in or on) the second section SC2 may be higher than that at (e.g., in or on) the first section SC1.

Referring to FIG. 6C, after the first rotation of the laser unit LS, the laser beam LB may also be emitted on (e.g., emitted to) the first section SC1. After the first rotation, the laser unit LS may emit the laser beam LB onto the preliminary electronic module SM-A (e.g., “a workpiece substrate”) while rotating several times along the moving path MP. For example, the laser unit LS may emit the laser beam LB while rotating about one to about 200 times along the moving path MP. Accordingly, the hole-forming area CA may be removed from the preliminary electronic module SM-A. Here, the second moving speed MS2 of the laser unit LS may be a constant or substantially constant speed.

According to an embodiment of the present disclosure, a start point and an end point of the emission of the laser beam LB onto the preliminary electronic module SM-A may be defined on the moving path MP. Thus, after the hole-forming area CA is removed from the active area AA, and when the hole-forming area CA which has been cut is observed by a microscope, no trace of the emission of the laser beam LB may be present (e.g., may be found).

In the present embodiment, the laser beam provided from the laser unit LS may be a pulse laser beam. Thus, when the moving path MP irradiated with the laser beam LB is enlarged, a portion irradiated with the laser beam LB may be formed as a dotted line.

In the present embodiment, the moving speed of the laser beam along the moving path MP may be about 50 mm/s to about 6000 mm/s.

In the present embodiment, a frequency of the laser beam may be about 100 kHz to about 20000 kHz.

In the present embodiment, power of the laser beam may be about 0.5 W to about 30 W.

Referring to FIG. 7, the hole-forming area CA may be removed from the preliminary electronic module SM-A by using the laser beam provided from the laser unit LS, and emitting the laser beam along the moving path MP. A portion from which the hole-forming area CA is removed may be defined as a module hole MH. The module hole MH may be defined by aligning the adhesive layer hole HH-A, the optical film hole HH-P, the panel hole HH, and the protective layer hole HH-T, which are illustrated in FIG. 3A.

The method for manufacturing an electronic apparatus includes forming the module hole MH in the preliminary electronic module SM-A to provide an electronic module SM. The method may further include removing the protective films PF1 and PF2 that are connected to (e.g., attached to or bonded to) at least one of a top surface S-U or a bottom surface S-B of the electronic module SM.

In the method for manufacturing an electronic apparatus, the moving path MP includes the area (e.g., SC1) which is not irradiated with the laser beam LB until the laser unit LS reaches the desired moving speed, and thus, the moving path MP may be irradiated with the laser beam LB at the same energy intensity. Accordingly, the module hole MH without particles may be provided in the active area AA, and the electronic panel EP having an improved reliability may be provided.

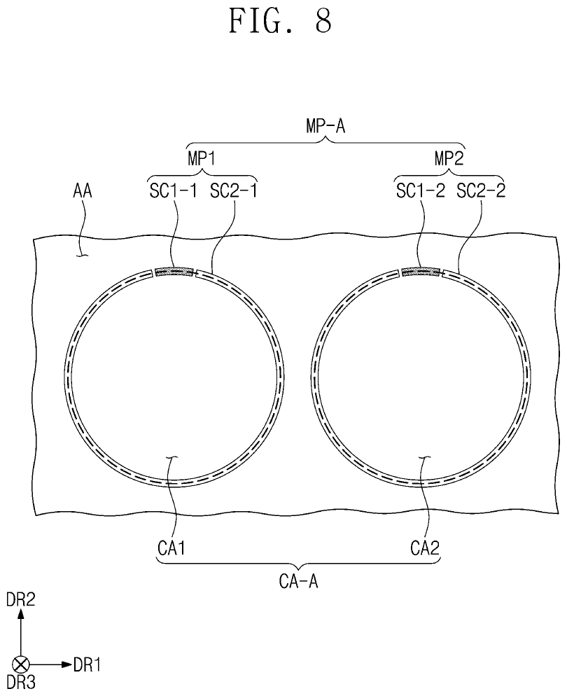

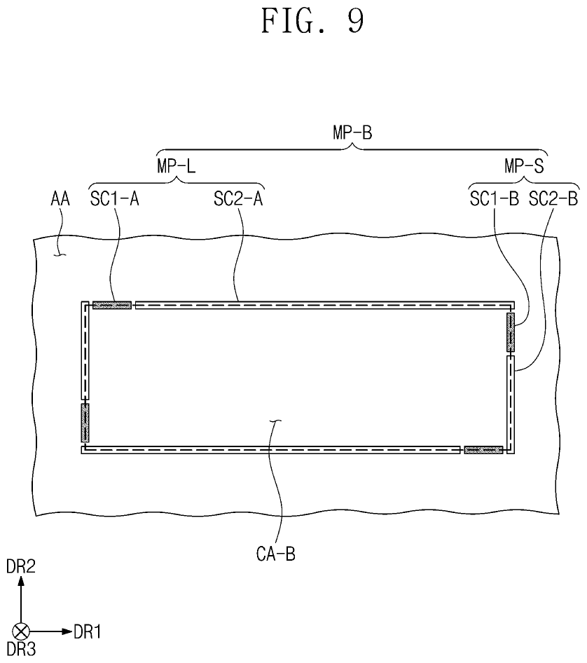

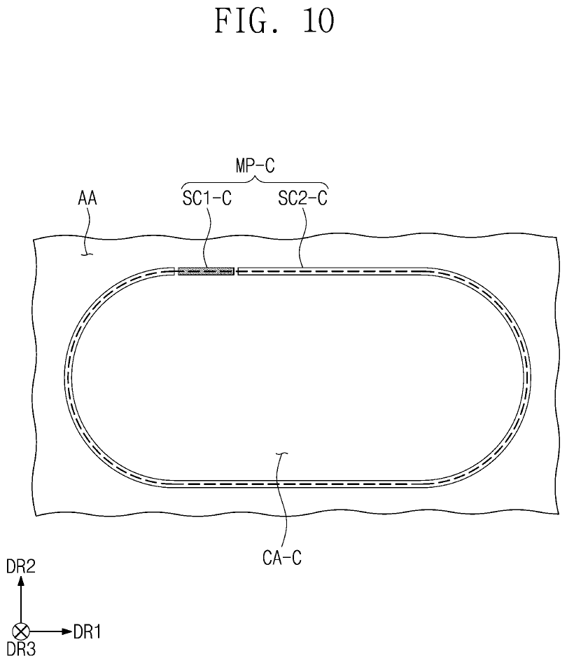

FIG. 8 is a plan view of a preliminary electronic module according to an embodiment of the present disclosure. FIG. 9 is a plan view of a preliminary electronic module according to an embodiment of the present disclosure. FIG. 10 is a plan view of a preliminary electronic module according to an embodiment of the present disclosure. In FIGS. 8 to 10, the same or substantially the same (or similar) reference symbols are used to refer to the same or substantially the same (or similar) elements of those of FIGS. 1 to 7, and thus, redundant descriptions thereof may not be repeated.

Referring to FIG. 8, in the present embodiment, a hole-forming area CA-A defined at (e.g., in or on) an active area AA may be provided in a plurality. For example, the hole-forming area CA-A may include a first hole-forming area CA1 and a second hole-forming area CA2. Thus, a moving path MP-A defined at (e.g., in or on) boundaries between the active area AA and the hole-forming area CA-A may also be provided in a plurality. For example, in the present embodiment, the moving path MP-A may include a first moving path MP1 and a second moving path MP2.

Each of the moving paths MP1 and MP2 may be divided into a section that is not irradiated with a laser beam during a first rotation of a laser unit (e.g., a laser source) LS, and a section that is irradiated with the laser beam LB (e.g., see FIG. 6B) after a desired moving speed of the laser unit LS is achieved.

For example, the first moving path MP1 may be divided into a first section SC1-1 at (e.g., in or on) which the laser beam LB is not irradiated during a first rotation and a second section SC2-1 at (e.g., in or on) which the laser beam LB is irradiated during the first rotation, and the second moving path MP2 may be divided into a first section SC1-2 at (e.g., in or on) which the laser beam LB is not irradiated during a first rotation and a second section SC2-2 at (e.g., in or on) which the laser beam LB is irradiated during the first rotation.

Referring to FIG. 9, in the present embodiment, a hole-forming area CA-B defined at (e.g., in or on) an active area AA may have a polygonal shape. In FIG. 9, the hole-forming area CA-B having a rectangular shape is illustrated as an example of the polygonal shape. However, the present disclosure is not limited thereto, and the polygonal shape of the hole-forming area CA-B is not limited to any particular example.

In the present embodiment, at least one section which is not irradiated with the laser beam LB during the first rotation of the laser unit LS (see FIG. 6B) may be provided in a moving path MP-B.

For example, the moving path MP-B may include a long-side moving path MP-L extending in a first direction DR1, and a short-side moving path MP-S extending in a second direction DR2. The long-side moving path MP-L may be divided into a first long-side section SC1-A and a second long-side section SC2-A, and the short-side moving path MP-S may be divided into a first short-side section SC1-B and a second short-side section SC2-B.

The second long-side section SC2-A and the first short-side section SC1-B may be adjacent to each other from a vertex portion in which the long-side moving path MP-L is in contact with the short-side moving path MP-S.

In the present embodiment, the laser unit LS (e.g., see FIG. 6B) may not emit the laser beam LB onto the first long-side section SC1-A and the first short-side section SC1-B during the first rotation, but may emit the laser beam LB onto the second long-side section SC2-A and the second short-side section SC2-B. However, the present disclosure is not limited thereto. For example, even though the hole-forming area CA-B has a polygonal shape, the moving path MP-B may include only one first section at (e.g., in or on) which the laser beam LB is not irradiated during the first rotation, but the present disclosure is not limited to any particular example.

Referring to FIG. 10, in the present embodiment, a hole-forming area CA-C defined at (e.g., in or on) an active area AA may have an elliptical shape. Thus, a moving path MP-C defined at (e.g., in or on) a boundary between the active area AA and the hole-forming areas CA-C may also have an elliptical shape. In the present embodiment, the moving path MP-C may include a first section SC1-C at (e.g., in or on) which the laser beam LB is not irradiated during a first rotation and a second SC2-C at (e.g., in or on) which the laser beam LB is irradiated during the first rotation.

In the method for manufacturing an electronic apparatus according to one or more example embodiments of the present disclosure, the moving path includes the area that is not irradiated with the laser beam until the laser unit reaches the desired moving speed, and thus, the moving path may be irradiated with the laser beam at the same energy intensity. Accordingly, the module hole without particles may be provided in the active area, and the electronic panel having improved reliability may be provided.

Although some example embodiments have been described, those skilled in the art will readily appreciate that various modifications are possible in the example embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific example embodiments disclosed herein, and that various modifications to the disclosed example embodiments, as well as other example embodiments, are intended to be included within the spirit and scope of the present disclosure as defined in the appended claims, and their equivalents.

What is claimed is:

1. A method for manufacturing an electronic apparatus, the method comprising:
providing a preliminary electronic module comprising an active area having a hole-forming area, and a peripheral area adjacent to the active area;
emitting a laser beam while rotating a laser source along a moving path defined along a boundary between the hole-forming area and the active area, the moving path being divided into a first section and a second section; and
removing the hole-forming area from the preliminary electronic module to form an electronic module having a module hole,
wherein, during a first rotation of the laser source along the moving path, the laser beam is not emitted on the first section, and the laser beam is emitted on the second section.

2. The method of claim 1, wherein, after the first rotation, the laser source emits the laser beam while rotating about one to about 200 times along the moving path.

3. The method of claim 1, wherein, during the first rotation of the laser source, a moving speed of the laser source at the second section is greater than a moving speed of the laser source at the first section, and
after the first rotation, a moving speed of the laser source is constant.

4. The method of claim 1, wherein a moving speed of the laser beam is about 50 mm/s to about 6000 mm/s.

5. The method of claim 1, wherein a power of the laser beam is about 0.5 W to about 30 W.

6. The method of claim 1, wherein a frequency of the laser beam is about 100 kHz to about 20000 kHz.

7. The method of claim 1, wherein a start point and an end point of the emitting of the laser beam are defined on the moving path.

8. The method of claim 1, wherein the laser beam is a pulse laser beam.

9. The method of claim 1, wherein the hole-forming area has one of a circular, elliptical, or polygonal shape.

10. The method of claim 1, wherein the hole-forming area comprises a plurality of hole-forming areas.

11. A method for manufacturing an electronic apparatus, the method comprising:
providing a preliminary electronic module comprising an active area having a hole-forming area, and a peripheral area adjacent to the active area;
emitting a laser beam while rotating a laser source along a moving path defined along a boundary between the hole-forming area and the active area, the moving path being divided into a first section and a second section; and
removing the hole-forming area from the preliminary electronic module to form an electronic module having a module hole,
wherein, during a first rotation of the laser source along the moving path, the laser source moves at a first speed at the first section, and at a second speed greater than the first speed at the second section.

12. The method of claim 11, wherein, during the first rotation of the laser source along the moving path, the laser beam is not emitted at the first section, and the laser beam is emitted at the second section.

13. The method of claim 12, wherein, after the first rotation, the laser source emits the laser beam while rotating about one to about 200 times along the moving path.

14. The method of claim 11, wherein, after the first rotation, a moving speed of the laser beam is about 50 mm/s to about 6000 mm/s.

15. The method of claim 11, wherein a power of the laser beam is about 0.5 W to about 30 W.

16. The method of claim 11, wherein a frequency of the laser beam is about 100 kHz to about 20000 kHz.

17. The method of claim 11, wherein a start point and an end point of the emitting of the laser beam are defined on the moving path.

18. The method of claim 11, wherein the laser beam is a pulse laser beam.

19. The method of claim 11, wherein the hole-forming area has one of a circular, elliptical, or polygonal shape.

20. A method for manufacturing an electronic apparatus, the method comprising:
providing a workpiece substrate comprising an active area having a hole-forming area and including a plurality of pixels, and a peripheral area adjacent to the active area;
emitting a laser beam while rotating a laser source along a moving path defined along a boundary between the hole-forming area and the active area, the moving path being divided into a first section and a second section; and
removing the hole-forming area from the workpiece substrate to form a module hole,
wherein, during a first rotation of the laser source along the moving path, the laser beam is not emitted at the first section, and the laser beam is emitted at the second section.
